(19) United States
(12) Patent Application Publication
(10) Pub. No.: US 2026/0011600 A1
(43) Pub. Date: Jan. 8, 2026

(54) METHOD FOR FORMING SOI SUBSTRATE

(71) Applicant: TAIWAN SEMICONDUCTOR MANUFACTURING COMPANY, LTD., Hsinchu (TW)

(72) Inventors: Hung-Chang CHANG, Tainan City (TW); Eugene I-Chun CHEN, Taipei City (TW); Yu-Hung CHENG, Tainan City (TW); Szu-Yu WANG, Hsinchu City (TW); Chia-Shiung TSAI, Hsinchu City (TW)

(73) Assignee: TAIWAN SEMICONDUCTOR MANUFACTURING COMPANY, LTD., Hsinchu (TW)

(21) Appl. No.: 18/765,607

(22) Filed: Jul. 8, 2024

(51) Int. Cl. H01L 21/762; H01L 21/265

(52) U.S. Cl. CPC H01L 21/76254; H01L 21/26506

(57) ABSTRACT

A method includes forming a first semiconductor layer over a substrate; forming a second semiconductor layer over the first semiconductor layer, wherein the first semiconductor layer has a higher germanium concentration than the second semiconductor layer; forming a semiconductor cap over the second semiconductor layer; forming a first bonding layer over the semiconductor cap; bonding the first boding layer to a second bonding layer over a carrier substrate to form a bonded structure; and performing a wafer splitting process to split the first semiconductor layer into a first portion and a second portion separated from each other, such that the first portion of the first semiconductor layer and the substrate are removed from the bonded structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 8 illustrate a method in various stages of forming a semiconductor-on-insulator (SOI) substrate in accordance with some embodiments of the present disclosure.

FIG. 9 illustrates a cross-sectional view where a semiconductor device is formed on a SOI substrate in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

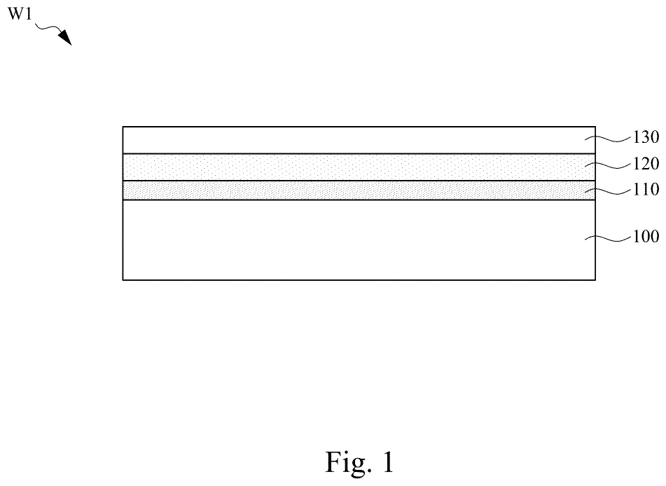

FIGS. 1 to 8 illustrate a method in various stages of forming a semiconductor-on-insulator (SOI) substrate in accordance with some embodiments of the present disclosure. Although FIGS. 1 to 8 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a wafer W1. The wafer W1 may include an initial structure having a substrate 100. The substrate 100 is a semiconductor substrate. Fox example, the substrate 100 may include silicon (Si). In some embodiments, the substrate 100 may include substantially pure silicon (Si) layer. The substrate 100 may be doped with suitable impurities, such as p-type or n-type impurities. For example, the substrate 100 is a p-type substrate including p-type dopants such as boron (B), gallium (Ga), indium (In), aluminium (Al), or the like. In alternative embodiments, the substrate 100 is an n-type substrate including n-type dopants, such as phosphorus (P), arsenic (As), or antimony (Sb), or the like.

A semiconductor layer 110 is formed over the substrate 100. In some embodiments, the semiconductor layer 110 may be formed over the substrate 100 using suitable epitaxial process, such as reduced pressure chemical vapor deposition (RPCVD). In some embodiments, the semiconductor layer 110 is made of silicon germanium (SiGe). In some embodiments, the semiconductor layer 110 may be doped with boron (SiGe:B). The doped semiconductor layer 110 (e.g., SiGe:B) may serve as a diffusion barrier layer or an implant capture layer to prevent implants diffusing from the doped semiconductor layer 110 to the substrate 100. In some embodiments, the germanium concentration of the semiconductor layer 110 may be in a range from about 20% to about 30%. In some embodiments, the concentration of boron may be in a range from about 5×10¹⁹ at/cm³ to about 5×10²⁰ at/cm³. In some embodiments, the thickness of the semiconductor layer 110 may be in a range from about 10 nm to about 100 nm. In other embodiments, the thickness of the semiconductor layer 110 may be in a range from about 10 nm to about 30 nm. In alternative embodiments, the thickness of the semiconductor layer 110 may be in a range from about 10 nm to about 25 nm. In some embodiments, the thickness of the semiconductor layer 110 is less than 30 nm.

A semiconductor layer 120 is formed over and in contact with the semiconductor layer 110. In some embodiments, the semiconductor layer 120 may be formed over the semiconductor layer 110 using suitable epitaxial process, such as selective epitaxial growth (SEG) process. In some embodiments, the semiconductor layer 120 is made of silicon germanium (SiGe). In some embodiments, the semiconductor layer 120 may be doped with boron (SiGe:B). The doped semiconductor layer 120 (e.g., SiGe:B) may also serve as a diffusion barrier layer. In some embodiments, the germanium concentration of the semiconductor layer 120 may be in a range from about 5% to about 10%. In some embodiments, the concentration of boron may be in a range from about 1×10¹⁸ at/cm³ to about 1×10²⁰ at/cm³. In some embodiments, the thickness of the semiconductor layer 120 may be in a range from about 200 nm to about 400 nm. In other embodiments, the thickness of the semiconductor layer 120 may be in a range from about 30 nm to about 70 nm.

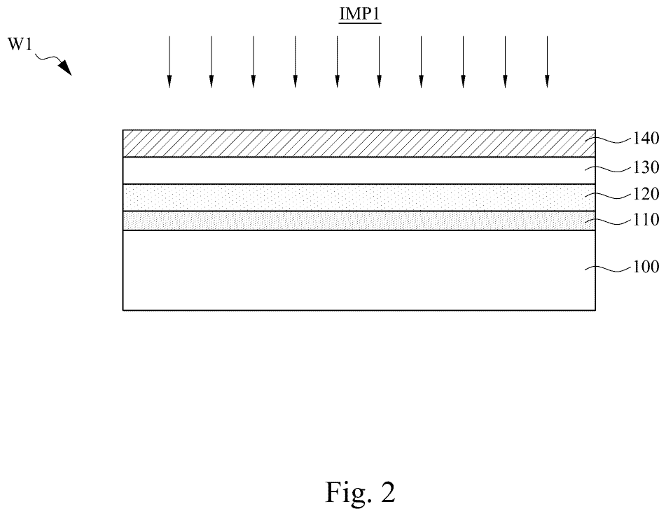

Although both of the semiconductor layers 110 and 120 may be made of boron-doped silicon germanium (SiGe:B), the semiconductor layers 110 and 120 may be different in compositions. In some embodiments, the semiconductor layer 110 may include higher boron concentration than the semiconductor layer 120. The higher boron concentration of the semiconductor layer 110 may include greater capability to capture implants generated from the following implantation process (e.g., the implantation process IMP1 of FIG. 2) than the semiconductor layer 120, such that implants may be confined at the semiconductor layer 110.

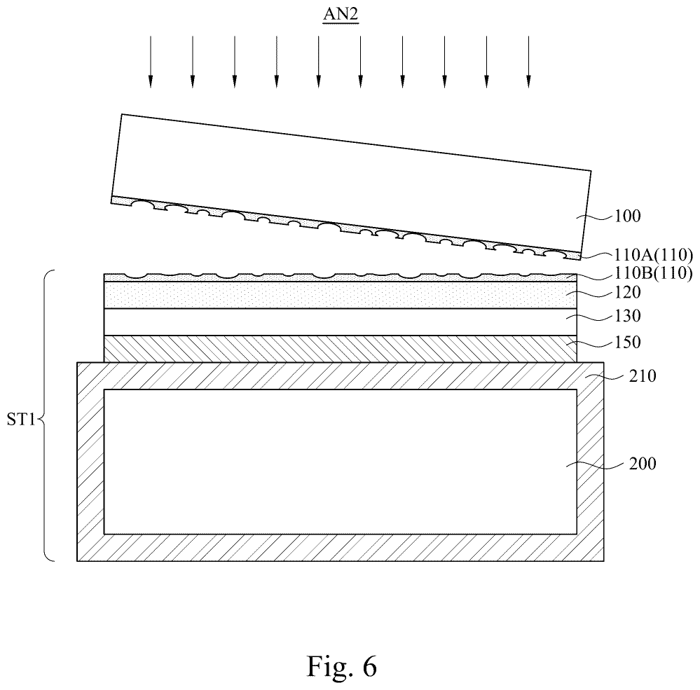

In some embodiments, the semiconductor layer 110 may include germanium concentration than the semiconductor layer 120. The higher germanium concentration of the semiconductor layer 110 may induce higher stress in the semiconductor layer 110, which is beneficial to create a cleavage plane in the semiconductor layer 110 during the following wafer splitting process (e.g., the wafer splitting process of FIG. 6). On the other hand, the lower germanium concentration of the semiconductor layer 120 may serve as a buffer layer to slow down the implantation species, such that the implants are able to be confined at the semiconductor layer 110. If the semiconductor layer 120 is absent (e.g., only the semiconductor layer 110 is formed), the implants may not be well controlled at the semiconductor layer 110. Moreover, the lower germanium concentration of the semiconductor layer 120 may result in the semiconductor layer 120 having less lattice mismatch with the subsequently formed semiconductor cap 130, which will improve the crystalline quality of the semiconductor cap 130. In some embodiments, the semiconductor layer 110 may be thinner than the semiconductor layer 120. The thinner semiconductor layer 110 may be beneficial to confine the implants in a small area, which will facilitate the following wafer splitting process.

A semiconductor cap 130 is formed over and in contact with the semiconductor layer 120. In some embodiments, the semiconductor cap 130 is formed on the semiconductor layer 120 using suitable epitaxial process, such as selective epitaxial growth (SEG) process. The semiconductor cap 130 may include silicon, and may also be referred to as a silicon cap. The semiconductor cap 130 may be doped with suitable impurities, such as p-type or n-type impurities. For example, the semiconductor cap 130 is a p-type substrate including p-type dopants such as boron (B), gallium (Ga), indium (In), aluminium (Al), or the like. In alternative embodiments, the semiconductor cap 130 is an n-type substrate including n-type dopants, such as phosphorus (P), arsenic (As), or antimony (Sb), or the like. In some embodiments, the semiconductor cap 130 may include the same dopants as the substrate 100. In some other embodiments, the semiconductor cap 130 may be un-doped. In some embodiments, the thickness of the semiconductor cap 130 may be in a range from about 15 nm to about 200 nm.

Reference is made to FIG. 2. A dielectric layer 140 is formed over and in contact with the semiconductor cap 130. The dielectric layer 140 may be made of oxide, such as silicon oxide. In some embodiments, the dielectric layer 140 may be formed using suitable deposition process, such as chemical vapor deposition (CVD). In some embodiments, the thickness of the dielectric layer 140 may range from 100 angstrom (Å) to 200 Å.

After the dielectric layer 140 is formed, an implantation process IMP1 is performed on the wafer W1 from the top surface of the dielectric layer 140. In greater detail, the implantation process IMP1 is performed using hydrogen gas (H₂). For example, hydrogen ions (H⁺) may be generated from the hydrogen gas (H₂) during the implantation process IMP1. The implantation energy of the implantation process IMP1 is controlled, such that the implantation species (e.g., hydrogen ions; H⁺) are able to reach the substrate 100 through the semiconductor cap 130 and the semiconductor layers 110 and 120. In some embodiments, the implantation energy of the implantation process IMP1 is in a range from about 5 keV to about 100 keV. The dosage of the hydrogen ions is in a range from about 1×10¹⁶ ions/cm² to about 1×10¹⁸ ions/cm². In some embodiments, the implantation process is performed at a tilted angle with respect to the top surface of the dielectric layer 140. For example, the tilted angle is in a range from about 5° to about 9°, such as 7° in some embodiments.

The implantation energy of the implantation process IMP1 is controlled, such that the implantation species is implanted to a desired position of the wafer W1. In some embodiments, the implantation energy of the implantation process IMP1 within the aforementioned range leads to the implantation species having a localized peak value within the semiconductor layer 110.

For example, in the cross-sectional view of FIG. 2, from the top surface of the semiconductor cap 130 to the bottom surface of the semiconductor cap 130, the implant concentration may increase from a first value to a second value greater than the first value.

Then, from the top surface of the semiconductor layer 120 to the bottom surface of the semiconductor layer 120, the implant concentration may increase from the second value to a third value greater than the second value.

Then, from the top surface of the semiconductor layer 110 to the bottom surface of the semiconductor layer 110, the implant concentration may increase from the third value to a first peak value and then decrease from the first peak value to a fourth value. In some embodiments, the fourth value is greater than the third value. That is, the average implant concentration in the semiconductor layer 110 is greater than the average implant concentrations in the semiconductor layer 120 and the semiconductor cap 130.

Then, from the top surface of the substrate 100 to the bottom surface of the substrate 100, the implant concentration may increase from the fourth value to a second peak value and then decrease from the second peak value to a fifth value that is lower than the fourth value. In some embodiments, the fifth value is the lowest value among the first, second, third, fourth, and the fifth values.

In some embodiments, the first peak value may be lower than the second peak value. This is because, in some embodiments, the implantation energy of the implantation process IMP1 may be controlled such that the implantation species are able to reach a position in the substrate 100 that is close to the interface between the substrate 100 and the semiconductor layer 110. The semiconductor layers 120 and 110 (e.g., SiGe:B) may serve as diffusion barrier layers, such that the implantation species are first slowed down through the semiconductor layer 120, and are captured (or trapped) at the semiconductor layer 110, resulting in a local peak concentration (e.g., the first peak value) within the semiconductor layer 110. In some embodiments, some implantation species may still penetrate through the semiconductor layer 110 and may be stopped at a region of the substrate 100 that is close to the semiconductor layer 110, resulting in another local peak concentration (e.g., the second peak value) within the substrate 100. In some embodiments, the first peak value is closer to the interface between the semiconductor layer 110 and the substrate 100 than to the interface between the semiconductor layer 110 and the semiconductor layer 120, and the second peak value is closer to the interface between the semiconductor layer 110 and the substrate 100 than to the bottom surface of the substrate 100.

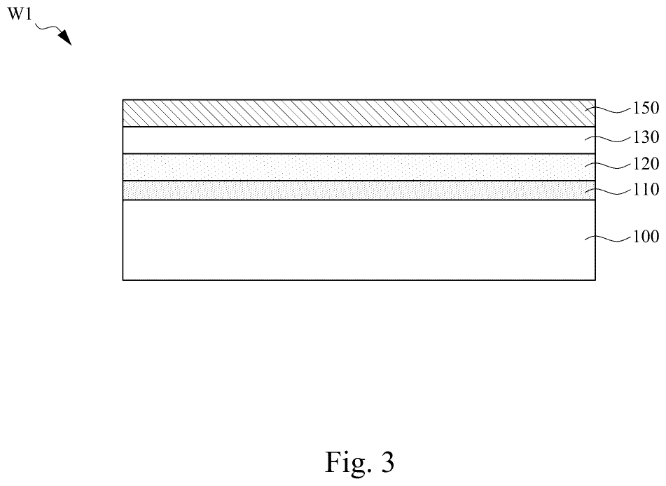

Reference is made to FIG. 3. After the implantation process IMP1 is complete, the dielectric layer 140 is removed to expose the top surface of the semiconductor cap 130. The dielectric layer 140 may be removed using suitable etching process, such as a wet etching, a dry etching, or combination thereof.

After the dielectric layer 140 is removed, a dielectric layer 150 is formed over and in contact with the semiconductor cap 130. The dielectric layer 150 may include oxide, such as silicon oxide. In some embodiments, the dielectric layer 150 may include a same material as the dielectric layer 140. In some embodiments, because the dielectric layer 150 is formed after the implantation process IMP1 as discussed in FIG. 2, the dielectric layer 150 does not undergo the implantation process IMP1, and thus the dielectric layer 150 is free of the implantation species (e.g., hydrogen) used in the implantation process IMP1.

In some embodiments, the dielectric layer 150 may be formed by a suitable deposition process, such as high density plasma (HDP) CVD. The thickness of the dielectric layer 150 may be in a range from about 0.01 μm to about 2.0 μm. In some embodiments, the dielectric layer 150 may serve as a bonding layer of the following wafer bonding process.

During the implantation process IMP1 as discussed in FIG. 2, the dielectric layer 140 may protect the semiconductor cap 130, such that the implantation species of the implantation process IMP1 would not be directly incident on the top surface of the semiconductor cap 130. However, the dielectric layer 140, which serves as a protective layer, may be damaged and may include several defects after the implantation process IMP1 is complete. Accordingly, by replacing the damaged dielectric layer 140 with the dielectric layer 150, the quality of subsequently formed SOI wafer may be improved. In some embodiments, the dielectric layer 140 can also be referred to as a sacrificial layer.

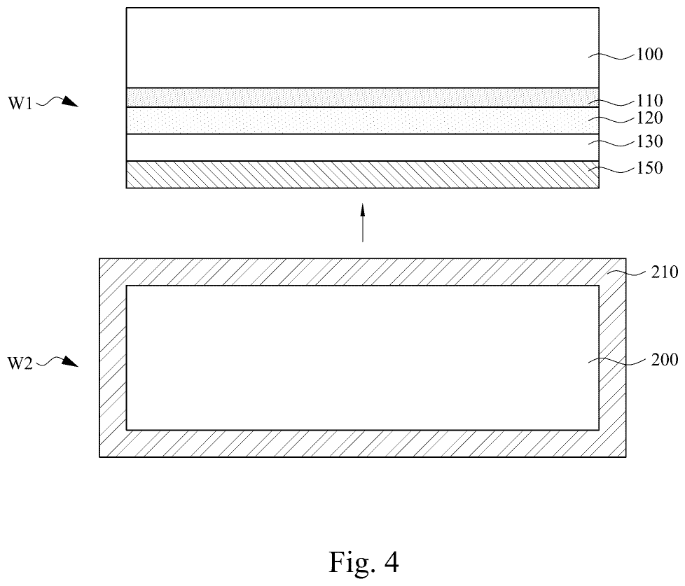

Reference is made to FIG. 4. A wafer W2 is provided. The wafer W2 includes a carrier substrate 200. In some embodiments, the carrier substrate 200 is a semiconductor substrate. Fox example, the carrier substrate 200 may include silicon (Si). In some embodiments, the carrier substrate 200 may include substantially pure silicon (Si) layer. The carrier substrate 200 may be doped with suitable impurities, such as p-type or n-type impurities. For example, the carrier substrate 200 is a p-type substrate including p-type dopants such as boron (B), gallium (Ga), indium (In), aluminium (Al), or the like. In alternative embodiments, the carrier substrate 200 is an n-type substrate including n-type dopants, such as phosphorus (P), arsenic (As), or antimony (Sb), or the like.

A dielectric layer 210 is formed over the carrier substrate 200. The dielectric layer 210 may include oxide, such as silicon oxide. The dielectric layer 210 may be formed using suitable method, such as thermal oxidation. In some embodiments, the dielectric layer 210 may extend along the top surface, the bottom surface, and the sidewalls of the carrier substrate 200.

A wafer bonding process is performed to bond the wafer W1 to a wafer W2. During the wafer bonding process, at least one of the wafers W1 and W2 is flipped over by 180 degrees. For example, in FIG. 4, the wafer W1 is flipped over by 180 degrees, such that the dielectric layer 150 of the wafer W1 faces the dielectric layer 210 of the wafer W2. The dielectric layers 150 and 210 are bonded with each other using a suitable technique. In some embodiments, the bonding process may further include applying surface treatments to the surfaces of the dielectric layers 150 and 210, respectively. The surface treatment may include a plasma treatment. The plasma treatment may be performed in a vacuum environment.

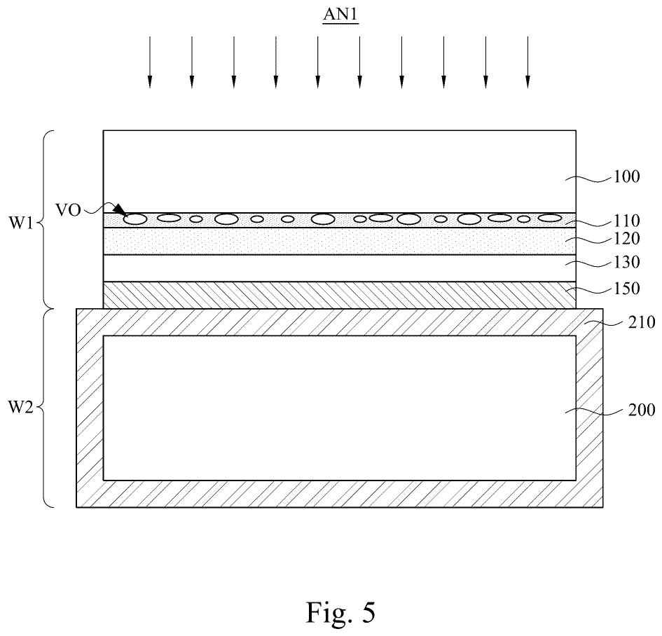

Reference is made to FIG. 5. The dielectric layers 150 and 210 are pressed against each other to initiate a pre-bonding of the wafers W1 and W2. The pre-bonding may be performed at room temperature (between about 21 degrees and about 27 degrees). After the pre-bonding, a bonding annealing process AN1 may be applied to the dielectric layers 150 and 210 that have already been pressed against each other. The bonding annealing process AN1 results in an increased bonding force between the dielectric layers 150 and 210, such that even if the dielectric layers 150 and 210 are no longer subjected to the pressing force, they will not delaminate or peel from each other. Therefore, the bonded wafers W1 and W2 collectively form a bonded structure.

The bonding annealing process AN1 is performed under a temperature in a range from about 300° C. to about 350° C. for about 1 hour to about 6 hours. As mentioned above, the semiconductor layer 110 includes higher implant concentration (e.g., hydrogen), and the hydrogen atoms may expand during the bonding annealing process AN1 and create several voids VO in the semiconductor layer 110, as shown in the cross-sectional view of FIG. 5. Moreover, as mentioned above, because the implantation species has a peak concentration near the interface between the semiconductor layer 110 and the substrate 100, the voids VO are closer to the interface between the semiconductor layer 110 and the substrate 100 than to the interface between the semiconductor layer 110 and the semiconductor layer 120. In some embodiments, because the semiconductor layer 120 has lower implant concentration, the semiconductor layer 120 may be substantially free of voids. In other embodiments, the semiconductor layer 120 may include less voids than the semiconductor layer 110.

As mentioned above, because the semiconductor layer 110 is a thin layer, most of the voids VO may be confined substantially at the same level. That is, most of the voids VO may horizontally arranged in the semiconductor layer 110 as shown in FIG. 5, and will be beneficial for the following wafer splitting process. However, if the semiconductor layer 110 is too thick, the voids VO may be randomly generated at different positions (e.g., along vertical direction) of the semiconductor layer 110, and would not improve the wafer splitting process. In some embodiments, at least one of the voids VO may include a height that is larger than half of the thickness of the semiconductor layer 110. In other embodiments, most (e.g., over 50%) of the voids VO may include a height that is larger than half of the thickness of the semiconductor layer 110.

Reference is made to FIG. 6. After the bonding annealing process AN1 is complete, a wafer splitting process is performed. The purpose of the wafer splitting process is to remove the substrate 100 from the bonded structure shown in FIG. 5. In greater detail, a wafer splitting annealing process AN2 is performed to the bonded structure shown in FIG. 5. The higher stress VO in the semiconductor layer 110 and the voids VO in the semiconductor layer 110 may be beneficial to create a cleavage plane in the semiconductor layer 110. Accordingly, the semiconductor layer 110 is split into separated portions 110A and 110B along the voids VO (see FIG. 5), in which the portion 110A of the semiconductor layer 110 is removed together with the substrate 100, leaving the portion 110B of the semiconductor layer 110 over the remaining stack ST1 of the bonded structure. The remaining stack ST1 may include the carrier substrate 200, the dielectric layer 210, the dielectric layer 150, the semiconductor cap 130, the semiconductor layer 120, and the portion 110B of the semiconductor layer 110. In some embodiments, the wafer splitting annealing process AN2 is performed under a temperature in a range from about 350° C. to about 600° C. for about 1 minute to about 30 minutes. In some embodiments, the temperature of the wafer splitting annealing process AN2 is higher than the temperature of the bonding annealing process AN1.

As mentioned above, because the voids VO are closer to the interface between the semiconductor layer 110 and the substrate 100 than to the interface between the semiconductor layer 110 and the semiconductor layer 120, the portion 110A of the semiconductor layer 110 may be thinner than the portion 110B of the semiconductor layer 120. In some embodiments, because the semiconductor layer 110 is split through the voids VO, the portions 110A and 110B of the semiconductor layer 110 may include cleavage surfaces, in which the cleavage surfaces may inherit the profiles of the voids VO, and thus the cleavage surfaces may be uneven surfaces.

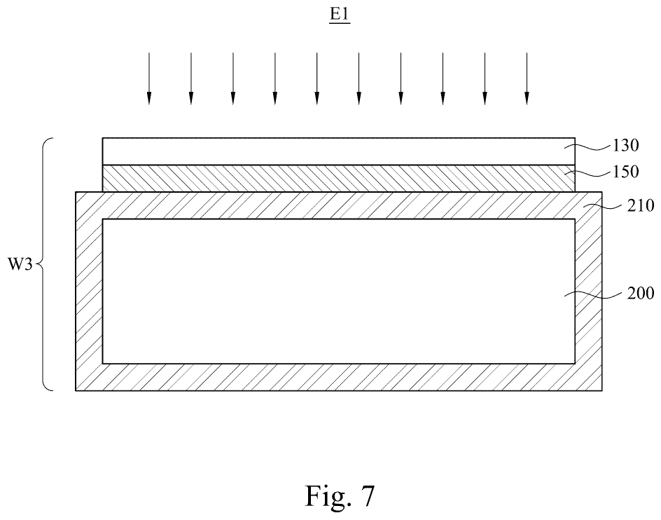

Reference is made to FIG. 7. With respect to the stack structure ST1 (see FIG. 6), an etching process E1 is performed to remove the portion 110B of the semiconductor layers 110 and the semiconductor layers 120, so as to expose the semiconductor cap 130. As a result, a wafer W3 is formed, in which the wafer W3 may include the carrier substrate 200, the dielectric layer 210, the dielectric layer 150, and the semiconductor cap 130. The wafer W3 may also be referred to as a semiconductor-on-insulator (SOI) wafer. The portion 110B of the semiconductor layers 110 and the semiconductor layers 120 may be removed using suitable etching process. For example, the etching process may be wet etch using 49% HF, 31% H₂O₂, and 99% CH₃COOH. In some embodiments, the ratio of the HF, H₂O₂, and CH₃COOH is about 1:2:3.

In some embodiments, a post annealing process may be performed prior to performing the etching process E1. The post annealing process is performed to recrystallize layers of the stack structure ST1, so as to repair defects in the layers. The post annealing process may be performed under a temperature in a range from about 1100° C. to about 1150° C. for about 0.5 hours to about 5 hours.

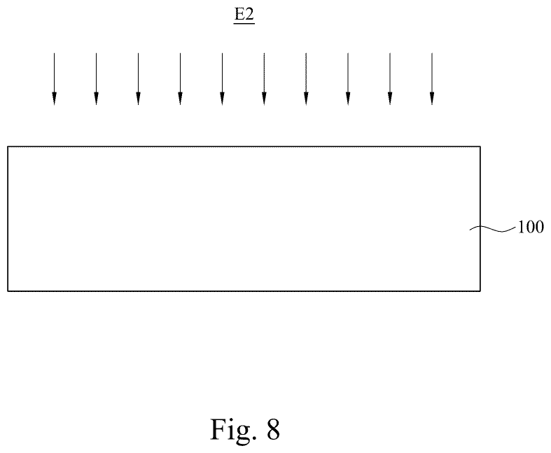

Reference is made to FIG. 8. With respect to the substrate 100 that is removed from the bonded structure. An etching process E2 is performed to remove the portion 110A of the semiconductor layer 110. Similarly, a post annealing process may be performed to the substrate 100 prior to performing the etching process E2. The post annealing process is performed to recrystallize the substrate 100, so as to repair defects in the substrate 100. The repaired substrate 100 can be used again to form the SOI wafer as discussed in FIGS. 1 to 7.

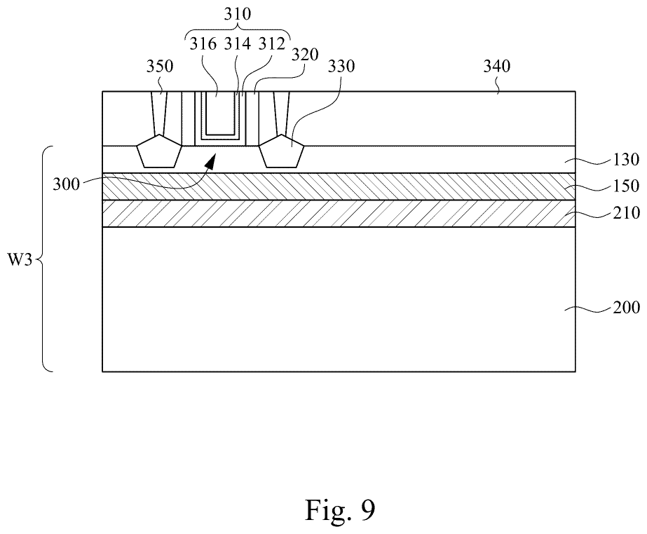

FIG. 9 illustrates a cross-sectional view where a semiconductor device is formed on a SOI substrate in accordance with some embodiments of the present disclosure. After the SOI wafer W3 is formed (see FIG. 7), at least one semiconductor device is formed over the SOI wafer W3. In greater detail, the semiconductor device is formed over the semiconductor cap 130 of the SOI wafer W3. Here, a transistor is used as an example of the semiconductor device, while other device may also be employed, and the present disclosure is not limited thereto.

A gate structure 310 is formed over the semiconductor cap 130 of the SOI wafer W3. The gate structure 310 may include a gate dielectric layer 312, a work function metal layer 314 over the gate dielectric layer 312, and a filling metal 316 over the work function metal layer 314.

In some embodiments, gate dielectric layer 312 may include an interfacial layer and a high-k dielectric layer over the interfacial layer. The interfacial layer may be made of oxide, such as aluminum oxide (Al₂O₃), silicon oxide (SiO₂), or the like. The high-k dielectric layer may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layer 314 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal 316 may include tungsten (W), aluminum (Al), copper (Cu), or another suitable conductive material(s).

Gate spacers 320 are formed on opposite sidewalls of the gate structure 310. In some embodiments, the gate spacers 320 may include one or more dielectrics, such as silicon oxide, silicon nitride, silicon oxynitride, silicon carbide, silicon carbonitride, the like, or a combination thereof.

Source/drain regions 330 are formed over the semiconductor cap 130 of the SOI wafer W3 and on opposite sides of the gate structure 310. In some embodiments, the source/drain regions 330 may include heavily-doped regions and relatively lightly-doped drain extensions, or LDD regions. The source/drain regions 330 may be formed, for example, by implanting dopants (e.g., As, P, B, In, or the like) using an ion implantation process.

The source/drain regions 330 may include an epitaxially grown region. For example, the semiconductor cap 130 of the SOI wafer W3 may be first to form recesses therein, a crystalline semiconductor material may be deposited in the recesses by a selective epitaxial growth (SEG) process. The crystalline semiconductor material may be elemental (e.g., Si, or Ge, or the like), or an alloy (e.g., Si₁₋ₓCₓ, or Si₁₋ₓGeₓ, or the like). A high dose (e.g., from about 10¹⁴ cm⁻² to 10¹⁶ cm⁻²) of dopants may be introduced into the source/drain regions 330 either in situ during SEG, or by an ion implantation process performed after the SEG, or by a combination thereof.

An interlayer dielectric (ILD) layer 340 is formed over the semiconductor cap 130 of the SOI wafer W3, covering the source/drain regions 330 and laterally surrounding the gate structure 310. In some embodiments, the ILD layer 340 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Source/drain contacts 350 may be formed in the ILD layer 340 and electrically connected to the respective source/drain regions 330. The source/drain contacts 350 may include a conductive liner and a contact plug over the conductive liner. In some embodiments, the conductive liner may include Ti, Ni, Pt, Co, TiN, TaN, Ta, or other suitable metals. The contact plug may include tungsten (W) or other suitable conductive materials, such as Al, Cu, Ru, Ni, Co, alloys of these, combinations thereof, and the like.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a SOI wafer. A first wafer includes a substrate, a first semiconductor layer over the substrate, a second semiconductor layer over the first semiconductor layer, and a semiconductor cap over the second semiconductor layer is provided. An implantation process is performed on the first wafer, the first semiconductor layer may serve as a diffusion barrier layer to slow down the implantation species, and the second semiconductor layer may serve as an implant capture layer to trap the implantation species within the second semiconductor layer, which results a high implantation concentration within the second semiconductor layer. After the implantation process, the first wafer is bonded to a second wafer. Then, a wafer splitting process is performed by splitting the second semiconductor layer, so as to form the SOI wafer. The high implantation concentration within the second semiconductor layer may facilitate the wafer splitting process, which in turn will improve the quality of the SOI wafer.

In some embodiments of the present disclosure, a method includes forming a first semiconductor layer over a substrate; forming a second semiconductor layer over the first semiconductor layer, wherein the first semiconductor layer has a higher germanium concentration than the second semiconductor layer; forming a semiconductor cap over the second semiconductor layer; forming a first bonding layer over the semiconductor cap; bonding the first bonding layer to a second bonding layer over a carrier substrate to form a bonded structure; and performing a wafer splitting process to split the first semiconductor layer into a first portion and a second portion separated from each other, such that the first portion of the first semiconductor layer and the substrate are removed from the bonded structure.

In some embodiments, the first semiconductor layer has a higher boron concentration than the second semiconductor layer.

In some embodiments, the first semiconductor layer is thinner than the second semiconductor layer.

In some embodiments, the method further includes performing an implantation process to implant implantation species in the first semiconductor layer prior to forming the first bonding layer over the semiconductor cap.

In some embodiments, bonding the first bonding layer to the second bonding layer over the carrier substrate comprises performing an annealing process, such that voids are formed in the first semiconductor layer.

In some embodiments, the implantation process is performed such that an implant concentration of the first semiconductor layer is higher than an implant concentration of the second semiconductor layer.

In some embodiments, the method further includes forming a dielectric layer over the semiconductor cap prior to performing the implantation process; and removing the dielectric layer after performing the implantation process and prior to forming the forming the first bonding layer over the semiconductor cap.

In some embodiments of the present disclosure, a method includes forming a first semiconductor layer over a substrate; forming a second semiconductor layer over the first semiconductor layer, wherein the first semiconductor layer has a higher boron concentration than the second semiconductor layer; forming a semiconductor cap over the second semiconductor layer; performing an implantation process to implant implantation species in the first semiconductor layer; forming a first bonding layer over the semiconductor cap after the implantation process is complete; bonding the first bonding layer to a second bonding layer over a carrier substrate to form a bonded structure; and performing a wafer splitting annealing process to split the first semiconductor layer into a first portion and a second portion separated from each other, such that the first portion of the first semiconductor layer and the substrate are removed from the bonded structure.

In some embodiments, the first semiconductor layer and the second semiconductor layer are made of silicon germanium.

In some embodiments, the implantation process is performed such that an implant concentration of the first semiconductor layer is higher than an implant concentration of the second semiconductor layer.

In some embodiments, the implantation process is performed such that the implantation species has a first peak concentration in the first semiconductor layer and a second peak concentration in the substrate, wherein the second peak concentration is higher than the first peak concentration.

In some embodiments, the first portion of the first semiconductor layer is thinner than the second portion of the first semiconductor layer.

In some embodiments, bonding the first bonding layer to the second bonding layer over the carrier substrate comprises performing an annealing process, such that the first semiconductor layer has more voids than the second semiconductor layer.

In some embodiments, the method further includes removing the second portion of the first semiconductor layer and the second semiconductor layer from the semiconductor cap after performing the wafer splitting annealing process.

In some embodiments of the present disclosure, a method includes forming a first silicon germanium (SiGe) layer over a silicon substrate; forming a second SiGe layer over the first SiGe layer; forming a silicon cap over the second SiGe layer; performing an implantation process to implant implantation species in the first SiGe layer; forming a first bonding layer over the silicon cap after the implantation process is complete; bonding the first bonding layer to a second bonding layer over a carrier substrate to form a bonded structure through a bonding annealing process, wherein voids are formed in the first SiGe layer as result of the bonding annealing process; performing a wafer splitting annealing process to split the first SiGe layer, along the voids of the first SiGe layer, into a first portion and a second portion separated from each other, such that the first portion of the first SiGe layer and the substrate are removed from the bonded structure.

In some embodiments, the first SiGe layer has a higher germanium concentration and a higher boron concentration than the second SiGe layer.

In some embodiments, the first SiGe layer is thinner than the second SiGe layer.

In some embodiments, a temperature of the bonding annealing process is lower than a temperature of the wafer splitting annealing process.

In some embodiments, the voids are closer to an interface between the first SiGe layer and the silicon substrate than to an interface between the first SiGe layer and the second SiGe layer.

In some embodiments, at least one of the voids includes a height that is larger than half of a thickness of the first SiGe layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor layer over a substrate;
forming a second semiconductor layer over the first semiconductor layer, wherein the first semiconductor layer has a higher germanium concentration than the second semiconductor layer;
forming a semiconductor cap over the second semiconductor layer;
forming a first bonding layer over the semiconductor cap;
bonding the first bonding layer to a second bonding layer over a carrier substrate to form a bonded structure; and
performing a wafer splitting process to split the first semiconductor layer into a first portion and a second portion separated from each other, such that the first portion of the first semiconductor layer and the substrate are removed from the bonded structure.

2. The method of claim 1, wherein the first semiconductor layer has a higher boron concentration than the second semiconductor layer.

3. The method of claim 1, wherein the first semiconductor layer is thinner than the second semiconductor layer.

4. The method of claim 1, further comprising performing an implantation process to implant implantation species in the first semiconductor layer prior to forming the first bonding layer over the semiconductor cap.

5. The method of claim 4, wherein bonding the first bonding layer to the second bonding layer over the carrier substrate comprises performing an annealing process, such that voids are formed in the first semiconductor layer.

6. The method of claim 4, wherein the implantation process is performed such that an implant concentration of the first semiconductor layer is higher than an implant concentration of the second semiconductor layer.

7. The method of claim 4, further comprising:
forming a dielectric layer over the semiconductor cap prior to performing the implantation process; and
removing the dielectric layer after performing the implantation process and prior to forming the forming the first bonding layer over the semiconductor cap.

8. A method, comprising:
forming a first semiconductor layer over a substrate;
forming a second semiconductor layer over the first semiconductor layer, wherein the first semiconductor layer has a higher boron concentration than the second semiconductor layer;
forming a semiconductor cap over the second semiconductor layer;
performing an implantation process to implant implantation species in the first semiconductor layer;
forming a first bonding layer over the semiconductor cap after the implantation process is complete;
bonding the first bonding layer to a second bonding layer over a carrier substrate to form a bonded structure; and
performing a wafer splitting annealing process to split the first semiconductor layer into a first portion and a second portion separated from each other, such that the first portion of the first semiconductor layer and the substrate are removed from the bonded structure.

9. The method of claim 8, wherein the first semiconductor layer and the second semiconductor layer are made of silicon germanium.

10. The method of claim 8, wherein the implantation process is performed such that an implant concentration of the first semiconductor layer is higher than an implant concentration of the second semiconductor layer.

11. The method of claim 8, wherein the implantation process is performed such that the implantation species has a first peak concentration in the first semiconductor layer and a second peak concentration in the substrate, wherein the second peak concentration is higher than the first peak concentration.

12. The method of claim 8, wherein the first portion of the first semiconductor layer is thinner than the second portion of the first semiconductor layer.

13. The method of claim 8, wherein bonding the first bonding layer to the second bonding layer over the carrier substrate comprises performing an annealing process, such that the first semiconductor layer has more voids than the second semiconductor layer.

14. The method of claim 8, further comprising removing the second portion of the first semiconductor layer and the second semiconductor layer from the semiconductor cap after performing the wafer splitting annealing process.

15. A method, comprising:
forming a first silicon germanium (SiGe) layer over a silicon substrate;
forming a second SiGe layer over the first SiGe layer;
forming a silicon cap over the second SiGe layer;
performing an implantation process to implant implantation species in the first SiGe layer;
forming a first bonding layer over the silicon cap after the implantation process is complete;
bonding the first bonding layer to a second bonding layer over a carrier substrate to form a bonded structure through a bonding annealing process, wherein voids are formed in the first SiGe layer as result of the bonding annealing process; and
performing a wafer splitting annealing process to split the first SiGe layer, along the voids of the first SiGe layer, into a first portion and a second portion separated from each other, such that the first portion of the first SiGe layer and the silicon substrate are removed from the bonded structure.

16. The method of claim 15, wherein the first SiGe layer has a higher germanium concentration and a higher boron concentration than the second SiGe layer.

17. The method of claim 16, wherein the first SiGe layer is thinner than the second SiGe layer.

18. The method of claim 15, wherein a temperature of the bonding annealing process is lower than a temperature of the wafer splitting annealing process.

19. The method of claim 15, wherein the voids are closer to an interface between the first SiGe layer and the silicon substrate than to an interface between the first SiGe layer and the second SiGe layer.

20. The method of claim 15, wherein at least one of the voids includes a height that is larger than half of a thickness of the first SiGe layer.
